(19) United States
(12) Patent Application Publication
(10) Pub. No.: US 2015/0372143 A1
(43) Pub. Date: Dec. 24, 2015

(54) SEMICONDUCTOR DEVICE AND METHOD FOR FABRICATING THE SAME

(71) Applicant: SAMSUNG ELECTRONICS CO., LTD., Gyeonggi-do (KR)

(72) Inventors: Dong-Il BAE, Incheon (KR); Kang-Ill SEO, Chungcheongbuk-do (KR)

(21) Appl. No.: 14/310,640

(22) Filed: Jun. 20, 2014

(51) Int. Cl. H01L 29/78; H01L 29/16; H01L 29/161; H01L 29/423

(52) U.S. Cl. CPC H01L 29/7851; H01L 29/42376; H01L 29/7856; H01L 29/7848; H01L 29/16; H01L 29/161

(57) ABSTRACT

A semiconductor device is provided. A fin type active pattern, extending in a first direction, protrudes from a substrate. A gate electrode is disposed on the fin type active pattern. The gate electrode extends in a second direction crossing the first direction. A recess region is disposed in the fin type active pattern disposed at one side of the gate electrode. The recess region includes an upper region having a first width in the first direction and a lower region having a second width smaller than the first width. A first epitaxial layer is disposed on the upper and lower regions of the recess region. A second epitaxial layer is disposed on the first epitaxial layer to fill the recess region.

### TECHNICAL FIELD

The present inventive concept relates to a semiconductor device and a method for fabricating the same.

### DISCUSSION OF RELATED ART

FinFET devices refer to three-dimensional (3D), multi-gate transistors of which a conducting channel is formed of a fin- or nanowire-shaped silicon body and a gate is formed on such silicon body. As feature sizes have become more fine, high leakage current due to short-channel effects may deteriorate device performance.

### SUMMARY

According to an exemplary embodiment of the inventive concept, a semiconductor device is provided. A fin type active pattern, extending in a first direction, protrudes from a substrate. A gate electrode is disposed on the fin type active pattern. The gate electrode extends in a second direction crossing the first direction. A recess region is disposed in the fin type active pattern disposed at one side of the gate electrode. The recess region includes an upper region having a first width in the first direction and a lower region having a second width smaller than the first width. A first epitaxial layer is disposed on the upper and lower regions of the recess region. A second epitaxial layer is disposed on the first epitaxial layer to fill the recess region.

According to an exemplary embodiment of the inventive concept, a method for fabricating a semiconductor device is provided. A fin type active pattern is formed to protrude from a substrate and extend in a first direction. First and second gate electrodes are formed on the fin type active pattern. The first and second gate electrodes extend in a second direction crossing the first direction. A first recess region is formed to have a first width in the first direction in the fin type active pattern disposed between the first and second gate electrodes. The first recess region undercuts the first and second gate electrodes. A second recess region is formed to extend downwardly from a bottom surface of the first recess region and have a second width smaller than the first width in the first direction. A first epitaxial layer is formed on the first and second recess regions. A second epitaxial layer is formed on the first epitaxial layer to fill the first and second recess regions.

A fin type active pattern is formed to protrude from a substrate and extend in a first direction. First and second gate electrodes are formed on the fin type active pattern. The first and second gate electrodes extend in a second direction crossing the first direction. A first spacer is formed on a first side surface of the first gate electrode. A second spacer is formed on a second side surface of the second gate electrode. The first and second side surfaces face each other. After the forming of the first and second spacers, an implantation process is performed on the fin type active pattern to form a doped region in the fin type active pattern disposed between the first and second electrodes. A first recess region is formed by removing the doped region. The first recess region is formed between the first and second gate electrodes and undercuts the first and second gate electrodes. The first recess region has a first width in the first direction. A second recess region is formed to extend downwardly from a bottom surface of the first recess region and have a second width smaller than the first width in the first direction. A first epitaxial layer is formed on the first and second recess regions. A second epitaxial layer is formed on the first epitaxial layer to fill the first and second recess regions.

### BRIEF DESCRIPTION OF THE DRAWINGS

These and other features of the present inventive concept will become more apparent by describing in detail exemplary embodiments thereof with reference to the accompanying drawings of which:

FIG. 1 is a plan view illustrating a semiconductor device according to an exemplary embodiment of the present inventive concept;

FIG. 2 is a perspective view illustrating the semiconductor device shown in FIG. 1;

FIG. 3A is a cross-sectional view taken along line A-A of FIG. 2, FIG. 3B is an enlarged sectional view illustrating portion ‘C’ of FIG. 3A, and FIG. 3C is a cross-sectional view taken along line B-B of FIG. 2;

FIG. 4 is a cross-sectional view illustrating a semiconductor device according to an exemplary embodiment of the present inventive concept;

FIG. 5 is a cross-sectional view illustrating a semiconductor device according to an exemplary embodiment of the present inventive concept;

FIG. 6 is a cross-sectional view illustrating a semiconductor device according to an exemplary embodiment of the present inventive concept;

FIGS. 7 to 13 illustrate process steps illustrating an exemplary embodiment of a method for fabricating the semiconductor device shown in FIG. 3A;

FIGS. 14 to 17 illustrate process steps illustrating an exemplary embodiment of a method for fabricating the semiconductor device shown in FIG. 3A;

FIGS. 18 to 20 illustrate process steps illustrating a method for fabricating the semiconductor device shown in FIG. 5;

FIG. 21 is a block diagram of an electronic system including a semiconductor device according to an exemplary embodiment of the present inventive concept; and

FIGS. 22 to 24 illustrate exemplary semiconductor systems including a semiconductor device according to an exemplary embodiment of the present inventive concept are applied.

### DETAILED DESCRIPTION OF EXEMPLARY EMBODIMENTS

Exemplary embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

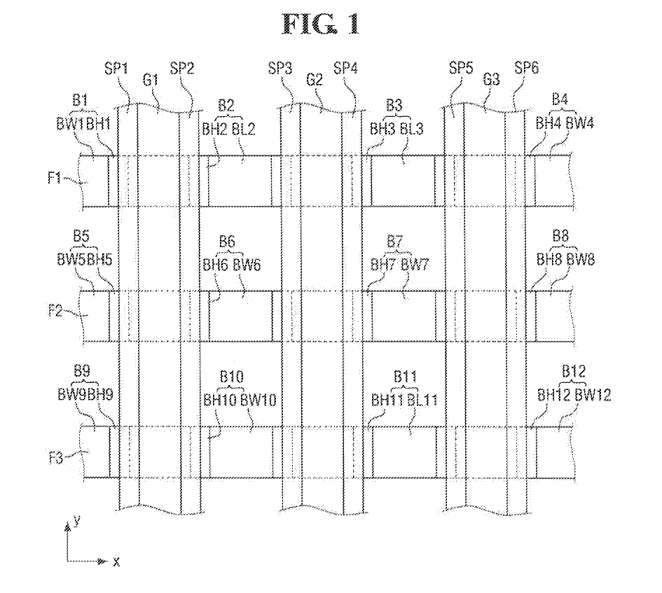

Hereinafter, a semiconductor device according to an exemplary embodiment of the present inventive concept will be described with reference to FIGS. 1 to 3C.

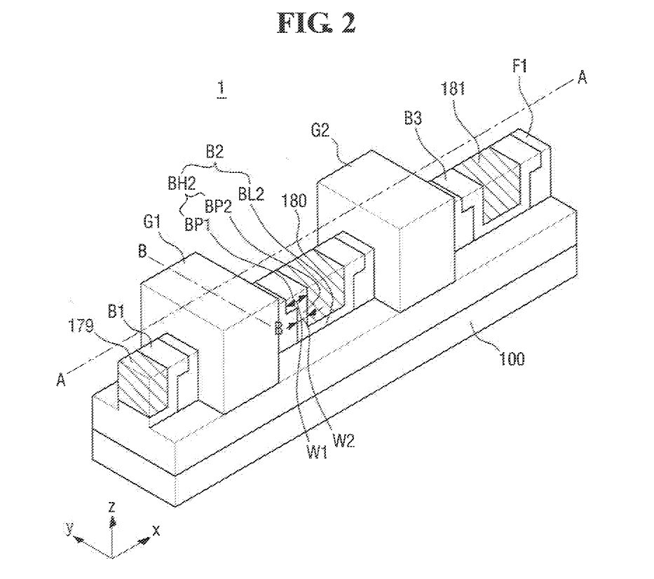

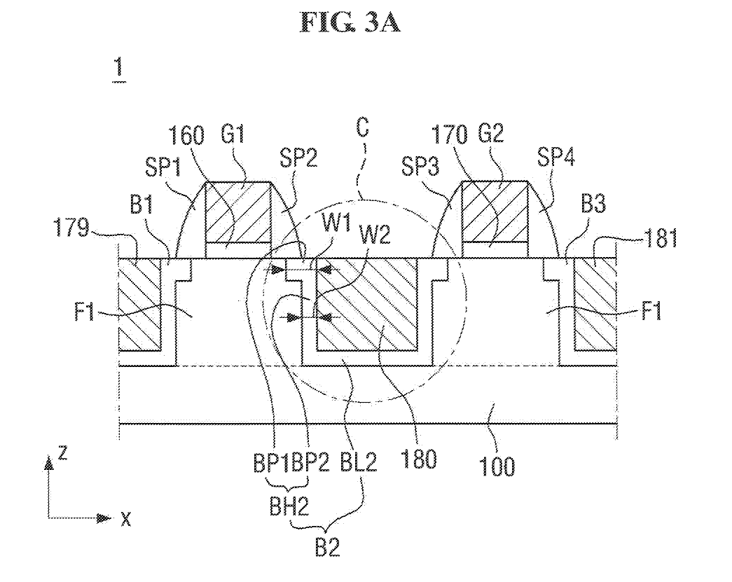

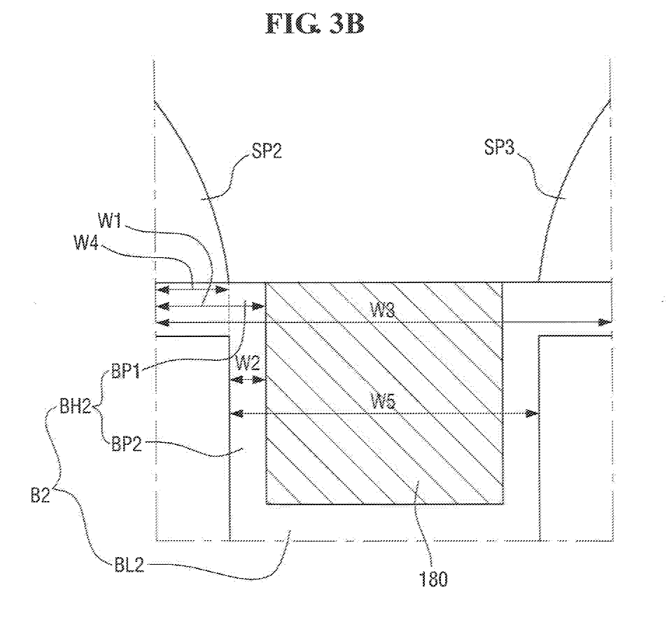

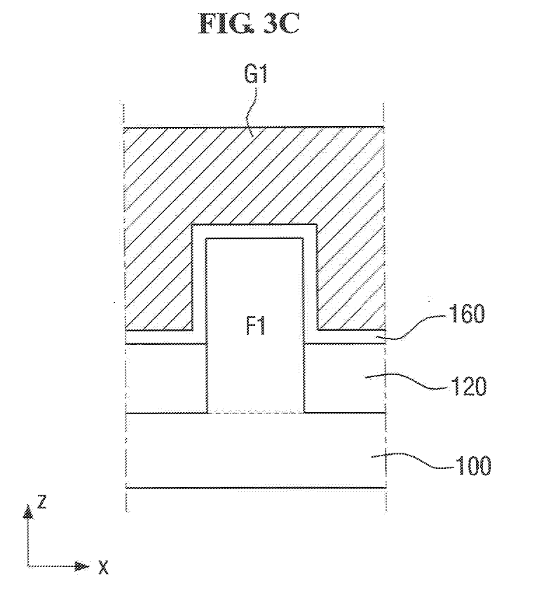

FIG. 1 is a plan view illustrating a semiconductor device according to an exemplary embodiment of the present inventive concept, FIG. 2 is a perspective view illustrating the semiconductor device shown in FIG. 1, and FIG. 3A is a cross-sectional view taken along line A-A of FIG. 2, FIG. 3B is an enlarged sectional view illustrating portion ‘C’ of FIG. 3A, and FIG. 3C is a cross-sectional view taken along line B-B of FIG. 2.

Hereinafter, the present inventive concept will be described with regard to the semiconductor device 1 including a fin type transistor (FinFET), but the present inventive concept is not limited thereto. However, the present inventive concept may also be applied to another type of semiconductor device having a stereoscopic shape (for example, a transistor using a nanowire).

Referring to FIG. 1, the semiconductor device 1 may include fin type active patterns F1 to F3, gate electrodes G1 to G3, spacers SP1 to SP6 and buffer layers B1 to B12.

The fin type active patterns F1 to F3 may extend in a first direction X.

In addition, the fin type active patterns (e.g., F1, F2 and F3) may be arranged to be adjacent to each other in a widthwise direction (i.e., in a second direction Y).

The gate electrodes G1 to G3 may extend lengthwise in the second direction Y crossing the first direction X and may be spaced apart from each other in the first direction X.

The spacers SP1 to SP6 may be formed on opposite surfaces of the gate electrodes G1 to G3.

The buffer layers B1 to B12 are disposed between each of the gate electrodes G1 to G3 and may partially overlap with the spacers SP1 to SP6.

For example, a buffer top portion BH2 of the second buffer layer B2, for example, may partially overlap with the second and third spacers SP2 and SP3.

Referring to FIG. 2, the first fin type active pattern F1 may extend lengthwise along the first direction X. Other fin type active patterns (e.g., F2 and F3) may extend lengthwise along the first direction X, as shown in FIG. 2.

The fin type active pattern F1 may be portion of the substrate 100 and may include an epitaxial layer grown from the substrate 100.

The fin type active pattern F1 may have a rectangular shape, but the present inventive concept is not limited thereto. The fin type active pattern F1 may be chamfered. For example, the fin type active pattern F1 may have round corners.

The fin type active pattern F1 is an active pattern used in a multi-gate transistor. Channels of the fin type active pattern F1 are formed on three surfaces of the fin type active pattern F1.

The gate electrodes G1 and G2 may be formed on the fin type active pattern F1 so as to cross the fin type active pattern F1. For example, a first gate electrode G1 and a second gate electrode G2 may be formed on the first fin type active pattern F1.

As shown in FIG. 3A, first and second spacers SP1 and SP2 may be formed on both sides of the first gate electrode G1, and third and fourth spacers SP3 and SP4 may be formed on both sides of the second gate electrode G2.

A source/drain region 180 may be formed in the first fin type active pattern F1 between the first and second gate electrodes G1 and G2.

For example, other source/drain regions 179 and 181 may also be formed in the first fin type active pattern F1 between the first and second gate electrodes G1 and G2. The source/drain regions 179, 180 and 181 have a higher N- or P-type impurity concentration than the buffer layers B1 to B3.

The buffer layers B1 to B3 may be formed in the first fin type active pattern Ft so as to surround the source/drain regions 179, 180 and 181.

For example, the buffer layer (e.g., the second buffer layer B2) may be formed to surround the source/drain region 180 and may include a buffer top portion BH2 forming a side surface of the second buffer layer B2 and a buffer bottom portion BL2 forming a bottom surface of the second buffer layer B2. In addition, the buffer top portion BH2 may include a first part BP1 and a second part BP2 having different widths in the first direction X. Here, the first part BP1 may have a first width W1 in the first direction X, the second part BP2 may have a second width W2 in the first direction X, and the first width W1 may be greater than the second width W2, but the present inventive concept is not limited thereto. Other buffer layers B1 and B3 may have the same structure and characteristics with the second buffer layer B2.

Referring to FIG. 3B, portion ‘C’ of FIG. 3A is enlarged.

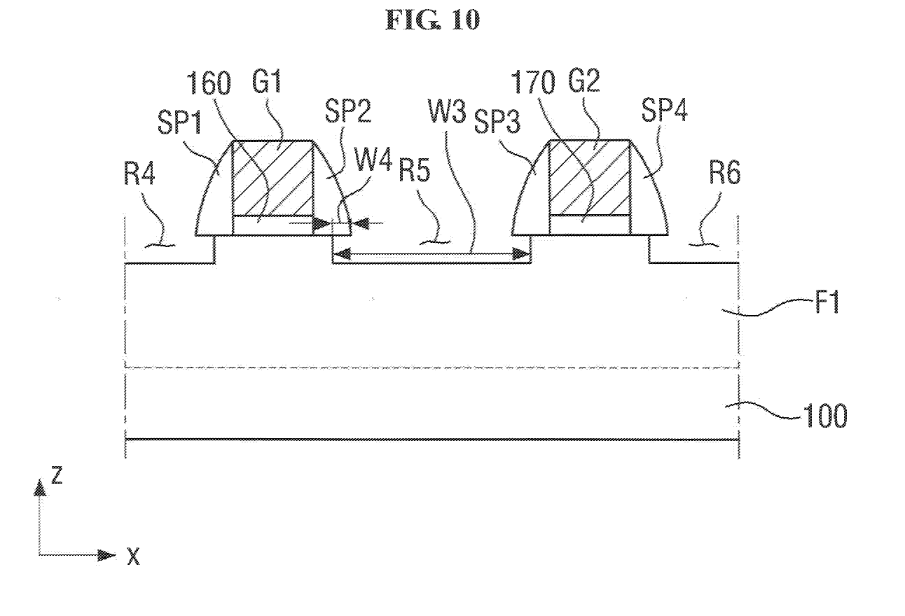

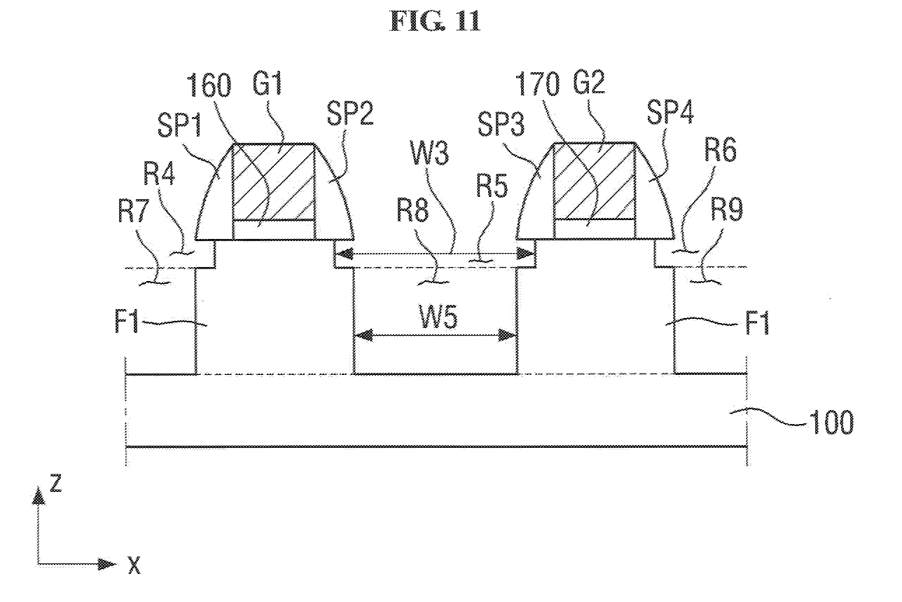

For example, the second buffer layer B2 and the source/drain region 180 may be formed to fill a recess region having a third width W3 (e.g., a recess region R5 of FIG. 10) and a recess region having a fifth width W5 smaller the third width W3 (e.g., a recess region R8 of FIG. 11). Here, the recess region having the third width W3 is formed to extend in a direction in which the gate electrodes G1 and G2 are disposed and may include a recess region having a fourth width W4 (e.g., a region obtained by forming the recess region R8 from the recess region R5, as shown in FIGS. 10 and 11). For example, the second buffer layer B2 is disposed on the sidewalls and the bottom of the recess region having the fifth width W5 while filling the recess region having the fourth width W4, and the source/drain region 180 may be formed on the second buffer layer B2 to fill the remaining region.

The respective recess regions will later be described.

Referring to FIGS. 3A and 3C, the first and second gate electrodes G1 and G2 may be formed on the gate insulation layers 160 and 170, respectively. In addition, the first and second gate electrodes G1 and G2 may include polysilicon and metal, but the present inventive concept is not limited thereto.

The gate insulation layer (e.g., 160) may be formed between the first fin type active pattern F1 and the first gate electrode G1. As shown in FIG. 3C, the gate insulation layer 160 may be formed on the top surface and an upper portion of the side surface of the first fin type active pattern F1. The gate insulation layer 160 may also be positioned between the first gate electrode G1 and the field insulation layer 120. The gate insulation layer 160 and the gate insulation layer 170 may have the same structure. The gate insulation layers 160 and 170 may include silicon oxide or a high-k material having a higher dielectric constant than silicon oxide.

Referring back to FIG. 1, the semiconductor device 1 may include a transistor formed using a gate-first process. The source/drain region 180 may be formed on the first fin type active pattern F1 after the gate electrodes G1 and G2 are formed. The source/drain region 180 may be formed by an epitaxial process, but the present inventive concept is not limited thereto.

When a p-type field effect transistor (pFET) may be formed on the first fin type active pattern F1, the source/drain region 180 may include a compressive stress material. For example, the compressive stress material may be a material having a greater lattice constant than silicon (Si), e.g., SiGe. The compressive stress material may apply a compressive stress to the first fin type active pattern F1, thereby improving mobility of carriers in a channel region of the first fin type active pattern F1.

When an n-type field effect transistor (nFET) may be formed on the first fin type active pattern F1, the source/drain region 180 may include the same material as the first fin type active pattern F1, or a tensile stress material. For example, when the first fin type active pattern F1 includes silicon, the elevated source/drain 407 may be silicon or a material having a smaller lattice constant than silicon (Si), e.g., SiC.

The source/drain region 180 may be formed of various materials according to whether the transistor formed on the first fin type active pattern F1 is a pFET or an nFET.

The spacers SP1 to SP4 may include at least one of oxide, nitride and oxynitride. The spacers SP1 to SP4 may be formed on both sidewalls of the gate electrodes G01 and G2.

The substrate 100 may be formed of at least one of Si, Ge, SiGe, GaP, GaAs, SiC, SiGeC, InAs and InP.

The buffer layers B1 to B3 may be formed in the first fin type active pattern F1 between the gate electrodes G1 and G2 and the source/drain regions 179, 180 and 181.

For example, the buffer layers B1 to B3 may be formed between channel regions (not shown) formed in the first fin type active pattern F1 positioned under the gate electrodes G1 and G2 and the source/drain regions 179, 180 and 181 and may surround side surfaces and bottom surfaces of the source/drain regions 179, 180 and 181.

The buffer layer (e.g., the second buffer layer B2) may include, for example, a buffer top portion BH2 forming a side surface of the second buffer layer B2 and a buffer bottom portion BL2 forming a bottom surface of the second buffer layer B2. The buffer top portion BH2 may include a first part BP1 adjacent to the channel region in the first direction X and a second part BP2 positioned under the first part BP1. The first to third buffer layers B1 to B3 may have the same structure and characteristics with the second buffer layer B2.

A width of the first part BP1 in the first direction X is a first width W1, a width of the second part BP2 in the first direction X is a second width W2, and the first width W1 may be greater than the second width W2, but the present inventive concept is not limited thereto. The first part BP1 may partially overlap with the second spacer SP2 and the third spacer SP3, and the second part BP2 need not overlap with the second spacer SP2 and the third spacer SP3 and may be positioned to be adjacent to a bottom portion of the first fin type active pattern F1.

The buffer layers B1 to B3 may have a lower concentration of an N- or P-type impurity than the source/drain region 180. For example, when the semiconductor device 1 is an nFET, the buffer layers B1 to B3 may include Si without Ge or Si with low-concentration Ge. The buffer layers B1 to B3 may be undoped or lightly doped with N-type impurity. When the semiconductor device 1 is an nFET, it may include an undoped buffer with carbon (e.g., an N-type impurity undoped buffer including SiC), but the present inventive concept is not limited thereto.

In addition, for example, when the semiconductor device 1 is a pFET, the buffer layers B1 to B3 may include Si with high-concentration Ge. The buffer layers B1 to B3 may be undoped or lightly doped with P-type impurity.

Here, the lightly doping with the N- or P-type impurity may mean doping the N- or P-type impurity in a concentration of 1e19 atoms/cm³ or less, but the present inventive concept is not limited thereto.

After forming a recess region having a greater width in its upper portion than in its lower portion in the first direction X, the buffer layers B1 to B3 are formed to fill the recess region. Accordingly, the buffer layers B1 to B3 including the first part BP1 are disposed on the fin type active pattern F1. Since the width of the first part BP1 in the first direction X is greater than that of the second part BP2 in the first direction X, the first part BP1 having a relatively large width in the first direction X prevents dopants of the source/drain region 180 from being diffused into the channel regions and prevents deterioration in device performance due to short-channel effects. In addition, since the second part BP2 has the second width W2 smaller than the first width W1 of the first part BP1, the flow of current may not be hindered, thereby preventing resistance from increasing.

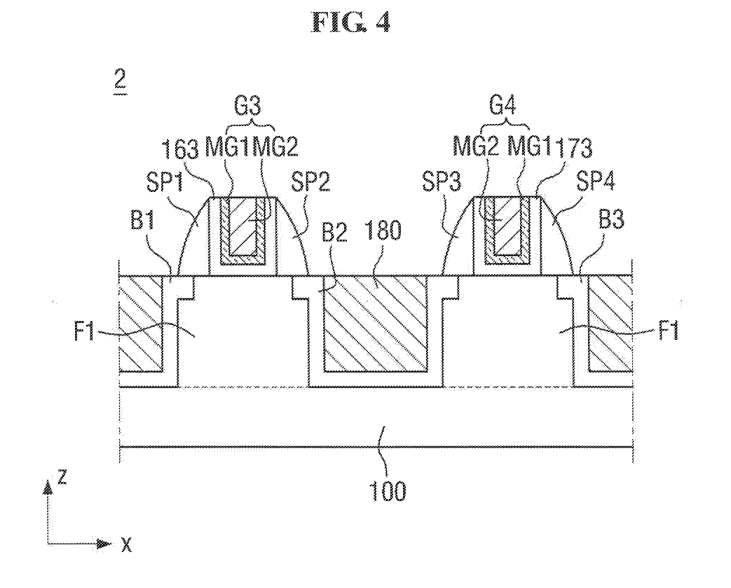

FIG. 4 is a cross-sectional view illustrating a semiconductor device according to an exemplary embodiment of the present inventive concept. For the sake of convenient explanation, the description of substantially the same elements as shown in FIGS. 1 to 3C will be omitted. Only two gate electrodes are illustrated in FIG. 4, but the present inventive concept is not limited thereto. For example, more gate electrodes other than the first and second gate electrodes G1 and G2 may be formed to be spaced apart from each other.

Referring to FIG. 4, the semiconductor device 2 may include the gate electrodes G1 and G2 having two or more metal layers MG1 and MG2. As shown, the gate electrodes G1 and G2 may have two or more metal layers MG1 and MG2 stacked one on another. The first metal layer MG1 may function to adjust a work function, and the second metal layer MG2 may function to fill a space formed by the first metal layer MG1. For example, the first metal layer MG1 may include at least one of TiN, TaN, TiC, and TaC. The second metal layer MG2 may include W or Al. The gate electrodes G1 and G2 may be formed by, for example, a replacement process (or a gate last process), but the present inventive concept is not limited thereto.

The gate insulation layers 163 and 173 may be U-shaped. For example, the gate insulation layer 163 may be formed on an inner surface defined by a top surface of the first fin type active pattern F1 and inner side surfaces of the spacers SP1 to SP2.

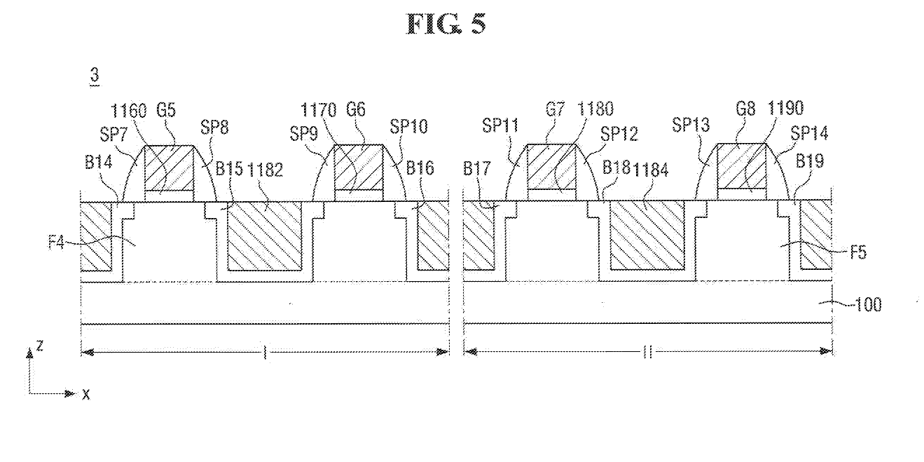

FIG. 5 is a cross-sectional view illustrating a semiconductor device according an exemplary embodiment of the present inventive concept. For the sake of convenient explanation, substantially the same content as described with reference to FIGS. 1 to 3C will be omitted. Only the semiconductor device having a gate first structure is illustrated in FIG. 5, but the present inventive concept is not limited thereto. For example, the semiconductor device according to an exemplary embodiment of the present inventive concept may have a gate last structure.

Referring to FIG. 5, a substrate 100 may include a first region I and a second region II.

The semiconductor device 3 may include a CMOS (Complementary Metal Oxide semiconductor) transistor. For example, the first region I of the substrate 100 may include one of a PMOS (P-type Metal Oxide Semiconductor) transistor and an NMOS (N-type Metal Oxide Semiconductor) transistor, and the second region II of the substrate 100 may include the other of a PMOS transistor and an NMOS transistor.

The first region I and the second region II of the substrate 100 includes semiconductor devices having the same structure with the semiconductor device 1 shown in FIG. 3A, and a detailed description thereof will be omitted.

When a PMOS transistor is formed in the first region I, buffer layers B14 to B16 of the first region I may include Si with high-concentration Ge. The buffer layers B14 to B16 may be undoped or lightly doped with P-type impurity.

When an NMOS transistor is formed in the second region II, the buffer layers B17 to B19 of the second region II may include Si without Ge or Si with low-concentration Ge. The buffer layers B17 to B19 may be undoped or lightly doped with N-type impurity.

For example, the semiconductor device 3 may be doped with impurities in various ways: 1) the buffer layers B14 to B16 of the first region I are undoped and the buffer layers B17 to B19 of the second region II are undoped; 2) the buffer layers B14 to B16 of the first region I are undoped and the buffer layers B17 to B19 of the second region II are lightly doped with N-type impurity; 3) the buffer layers B14 to B16 of the first region I are lightly doped with P-type impurity and the buffer layers B17 to B19 of the second region II are undoped; and 4) the buffer layers B4 to B16 of the first region I are lightly doped with P-type impurity and the buffer layers B17 to B19 of the second region II are lightly doped with N-type impurity.

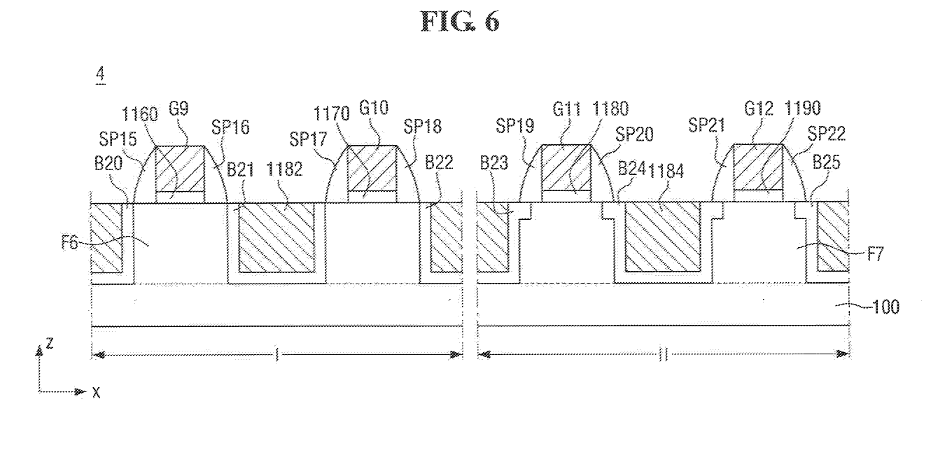

FIG. 6 is a cross-sectional view illustrating a semiconductor device according to an exemplary embodiment of the present inventive concept. For the sake of convenient explanation, the description of substantially the same elements as shown in FIGS. 1 to 3C and FIG. 5 will be omitted. The semiconductor device 4 may be formed by a gate-first process, but the present inventive concept is not limited thereto. For example, the semiconductor device 4 may be formed by a gate-last process.

Referring to FIG. 6, a substrate 100 may include a first region I and a second region II.

The semiconductor device 4 may include a CMOS transistor. For example, the first region I of the substrate 100 may include one of a PMOS transistor and an NMOS transistor, and the second region II of the substrate 100 may include the other of a PMOS transistor and an NMOS transistor.

Buffer layers may have different shapes in the first and second regions I and II. For example, the buffer layers B21 and B22 of the region I may be U-shaped, having uniform thickness; the buffer layer B23 to 25 of the region II may have the same shape with the semiconductor device 1 shown in FIG. 3A. For example, the width of an upper portion in the buffer layers B23 to B25 may be greater than the width of a lower portion in the buffer layers B23 to B25.

The semiconductor device of the second region II has the same structure with the semiconductor device 1 shown in FIG. 3A, and a detailed description thereof will be omitted.

The semiconductor device of the first region I is substantially the same with the semiconductor device of the second region II, except for the differences stated above, and a detailed description thereof will be omitted.

The semiconductor device 4 may be doped with impurities in various ways: 1) the buffer layers B14 to B16 of the first region I are undoped and the buffer layers B17 to B19 of the second region II are undoped; 2) the buffer layers B14 to B16 of the first region I are undoped and the buffer layers B17 to B19 of the second region II are lightly doped with N-type impurity; 3) the buffer layers B14 to B16 of the first region I are lightly doped with P-type impurity and the buffer layers B17 to B19 of the second region II are undoped with N-type impurity; and 4) the buffer layers B14 to B16 of the first region I are lightly doped with P-type impurity and the buffer layers B7 to B9 of the second region II are lightly doped with N-type impurity.

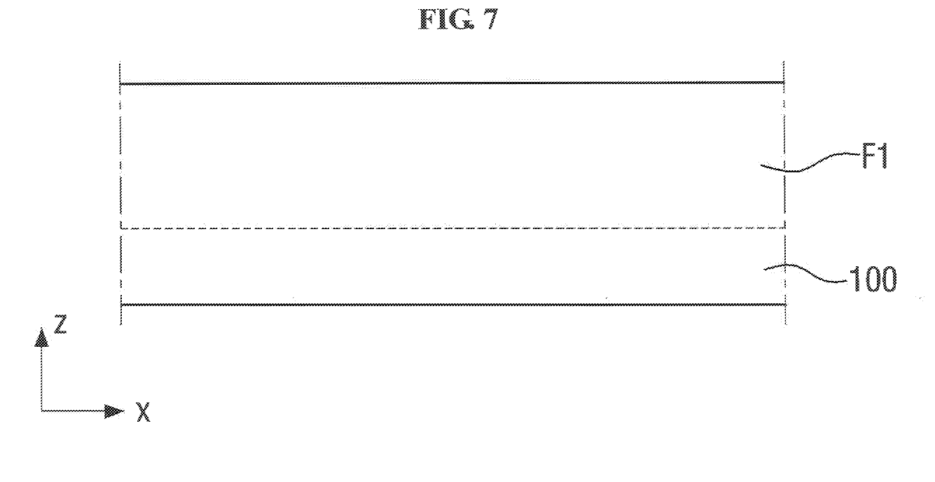

Hereinafter, an exemplary embodiment of a method for fabricating the semiconductor device shown in FIG. 3A will be described with reference to FIGS. 7 to 13.

FIGS. 7 to 13 illustrate process steps illustrating an exemplary embodiment of a method for fabricating the semiconductor device shown in FIG. 3A. For the sake of convenient explanation, the description of substantially the same elements as shown in FIGS. 1 to 3C will be omitted.

Referring to FIG. 7, the first fin type active pattern F1 is formed to extend from the substrate 100 in the first direction X. Here, the first fin type active pattern F1 may be portion of the substrate 100 and may include an epitaxial layer grown from the substrate 100.

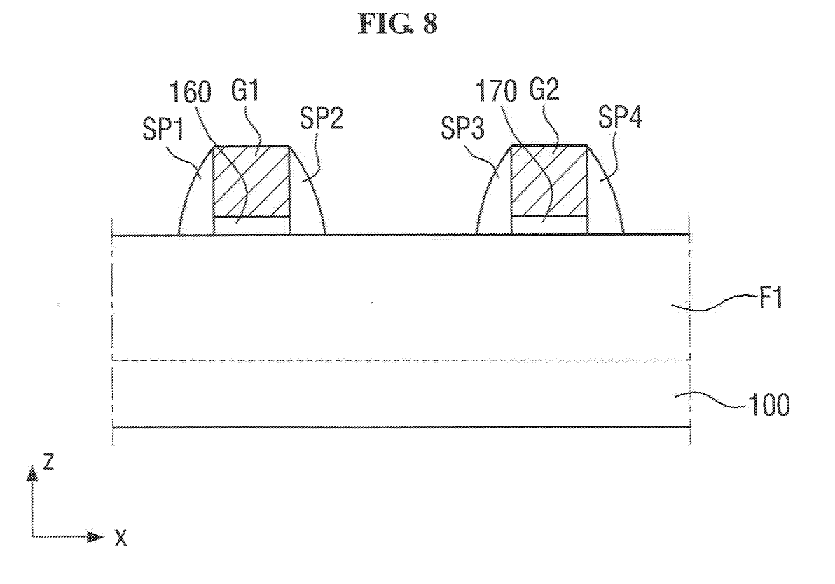

Referring to FIG. 8, the first gate electrode G1 and the second gate electrode G2 extending in the second direction Y crossing the first direction X and spaced apart from each other in the first direction X may be formed on the first fin type active pattern F1.

For example, a gate insulation layer (not shown) and a gate layer (not shown) are sequentially formed on the first fin type active pattern F1, and the gate insulation layer and the gate layer are etched, thereby forming the first and second gate electrodes G1 and G2 and the first and second gate insulation layers 160 and 170 shown in FIG. 8.

The spacers SP1 to SP4 may be formed on both side surfaces of the first and second gate electrodes G1 and G2.

After the first and second gate electrodes G1 and G2 and the first and second gate insulation layers 160 and 170 are formed, a first interlayer dielectric layer (not shown) is formed to completely cover the first and second gate electrodes G1 and G2, and the first interlayer dielectric layer is planarized until top surfaces of the first and second gate electrodes G1 and G2 are exposed. The planarization process may include, for example, a CMP (Chemical Mechanical Polishing) process, but the present inventive concept is not limited thereto. After the planarization process, the first interlayer dielectric layer (not shown) is etched, thereby forming the spacers SP1 to SP4 on both side surfaces of the gate electrodes G01 and G2, respectively. Here, the etching of the first interlayer dielectric layer may be performed using a reactive ion etching (RIE) process, but the present inventive concept is not limited thereto.

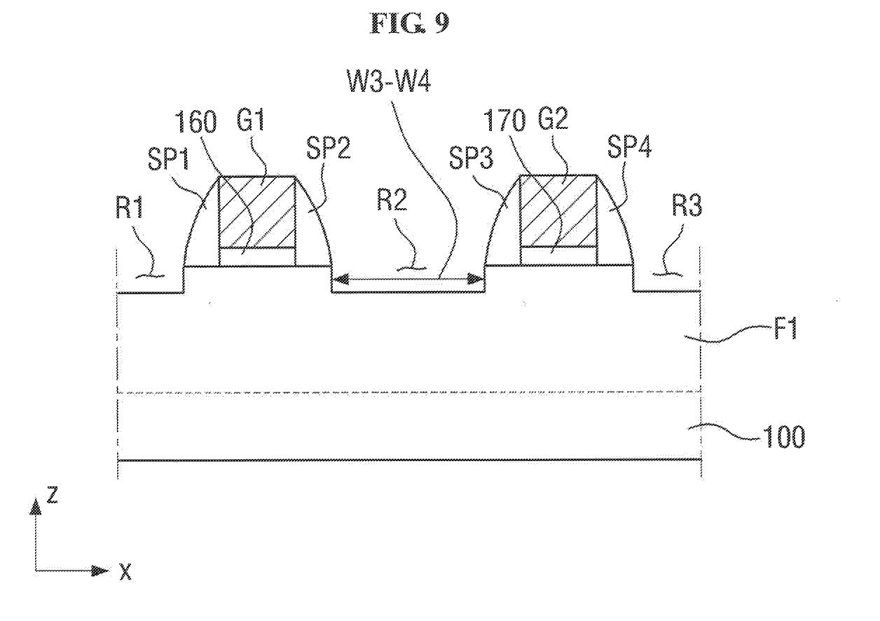

Referring to FIG. 9, a first anisotropic etching process is performed on the top portion of the first fin type active pattern F1 between the first gate electrode G1 and the second gate electrode G2.

For example, first to third recess regions R1 to R3 may be formed by etching only the top portion of the first fin type active pattern F1. Here, the first anisotropic etching process may be performed using a dry etching process, but the present inventive concept is not limited thereto. The first to third recess regions R1 to R3 have a width in the first direction X, corresponding to a width obtained by subtracting the fourth width W4 from the third width W3, as described above with reference to FIG. 3A.

Referring to FIG. 10, an isotropic etching process may be performed on the resulting structure of FIG. 9.

For example, the isotropic etching process may be performed on the first to third recess regions R1 to R3, thereby resulting in fourth to sixth recess regions R4 to R6. The fourth to sixth recess regions R4 to R6 may partially undercut the spacers SP1 to SP4. For example, the fourth to sixth recess regions R4 to R6 may partially overlap the spacers SP1 to SP4. For example, the fourth to sixth recess regions R4 to R6 may have a third width W3 in the first direction X and the regions of the fourth to sixth recess regions R4 to R6 overlapping with the spacers SP1 to SP4 may have a width W4 in the first direction X. For example, the isotropic etching process may include a wet etching process, and the spacers SP1 to SP4 and the first fin type active pattern F1 may have etching selectivity in the wet etching process.

Referring to FIGS. 9 and 10, the isotropic etching process may be performed after performing the first anisotropic etching process, but the present inventive concept is not limited thereto. Rather, an isotropic etching process may be performed without performing an anisotropic etching process before the isotropic etching process.

Referring to FIG. 11, a second anisotropic etching process may be performed on the resulting structure of FIG. 10.

For example, the second anisotropic etching process is performed on the fourth to sixth recess regions R4 to R6, thereby forming seventh to ninth recess regions R7 to R9 extending downward from the fourth to sixth recess regions R4 to R6. The seventh to ninth recess regions R7 to R9 may have a fifth width W5 smaller than the third width W3 in the first direction X.

The fifth recess region R5 and the eighth recess region R8 will now be described by way of example. The width of the fifth recess region R5 disposed on the first fin type active pattern F1 in the first direction X may be different from the width of the eighth recess region R8 disposed under the first fin type active pattern F1 in the first direction X. The third width W3 of the fifth recess region R5 may be greater than the fifth width W5 of the eighth recess region R8, but the present inventive concept is not limited thereto.

A depth of a recess region formed by the second anisotropic etching process is greater than a depth of a recess region formed by the first anisotropic and isotropic etching process. The depth is measured along a third direction of Z. For example, an etching amount of the second anisotropic etching process may be greater than a total etching amount of the first anisotropic etching process and the isotropic etching process, but the present inventive concept is not limited thereto.

In a case where the isotropic etching process is performed without performing the first anisotropic etching process before the isotropic etching process, the etching amount of the second anisotropic etching process may be greater than that of the isotropic etching process.

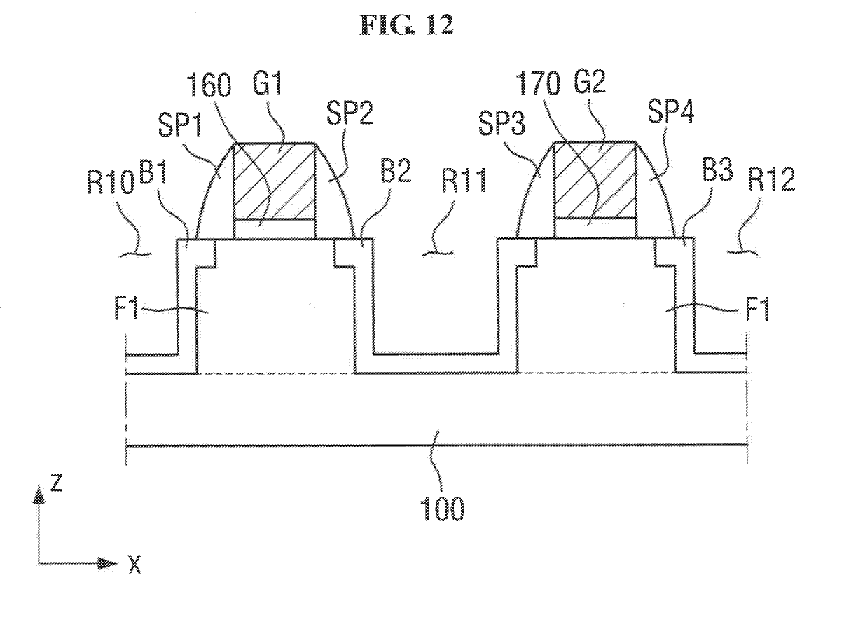

Referring to FIG. 12, the buffer layers B1 to B3 are formed on the first fin type active pattern F1 exposed by the seventh to ninth recess regions R4 to R9, respectively.

For example, the buffer layers B1 to B3 may be formed by, for example, an epitaxial growth method, but the present inventive concept is not limited thereto. The buffer layers B1 to B3 may be disposed on sidewalls and bottoms of the seventh to ninth recess regions R7 to R9 while filling regions of the fourth to sixth recess regions R4 to R6 partially overlapping with the spacers SP1 to SP4. The thicknesses of the buffer layers B1 to B3 formed in the fourth to sixth recess regions R4 to R6 may be greater than the buffer layers B1 to B3 formed in the seventh to ninth recess regions R7 to R9. The thickness is measured in the first direction of X.

Consequently, since the third width W3 of each of the fourth to sixth recess regions R4 to R6 is different from the fifth width W5 of each of the seventh to ninth recess regions R7 to R9, the widths of the buffer layers B1 to B3 disposed on the first fin type active pattern F1 in the first direction X may be different from those of the buffer layers B1 to B3 disposed under the first fin type active pattern F1 in the first direction X. As shown in FIG. 3A, the first width W1 of the first part BP1 is greater than the second width W2 of the second part BP2.

The buffer layers B1 to B3 formed in the recess regions R4 to R9 may define 10th to 12th recess regions R10 to R12.

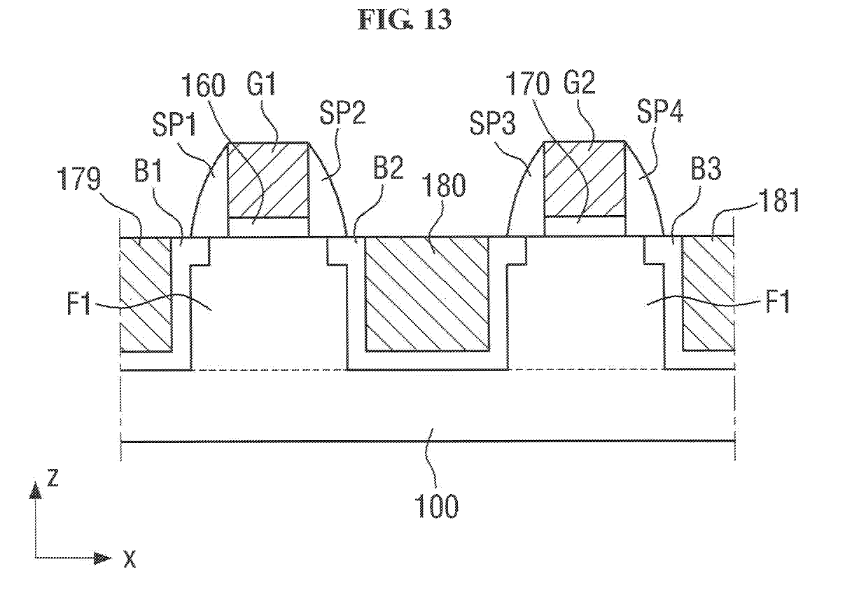

Referring to FIG. 13, source/drain regions 179, 180 and 181 are stacked in the 10th to 12th recess regions R10 to R12.

For example, the source/drain regions 179, 180 and 181 may be formed by, for example, an epitaxial growth method, but the present inventive concept is not limited thereto.

Concentrations of N- or P-type impurities doped into the source/drain regions 179, 180 and 181 may be higher than those of N- or P-type impurities doped into the buffer layers B1 to B3. The impurities doped into the buffer layers B1 to B3 are the same as described above, and repeated descriptions thereof will be omitted.

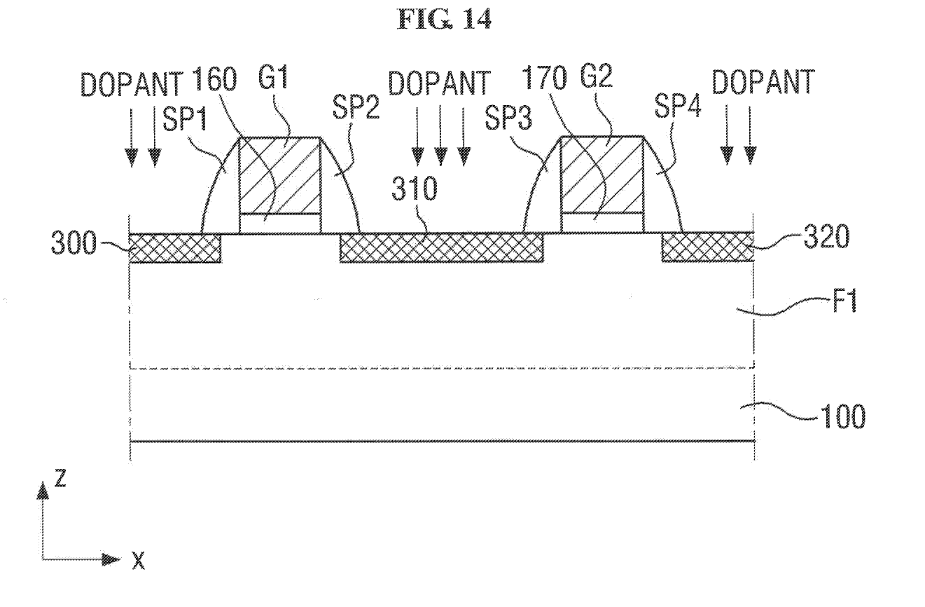

Hereinafter, an exemplary embodiment of a method for fabricating the semiconductor device shown in FIG. 3A will be described with reference to FIGS. 14 to 17.

FIGS. 14 to 17 illustrate process steps illustrating an exemplary embodiment of a method for fabricating the semiconductor device shown in FIG. 3A.

The detailed description of the same elements as in the above embodiment will be omitted.

Referring to FIG. 14, first and second gate electrodes G1 and G2 and first to fourth spacers SP1 to SP4 are formed on the first fin type active pattern F1, followed by implanting a dopant into the first fin type active pattern F1. The dopant used in the ion implantation process may increase an etch rate of the first fin type active pattern F1. Such dopant may be selected based on substrate material(s) and the etchant used in the subsequent etching process. The dopant may include, for example, at least one of carbon, phosphorus and arsenic. For example, carbon may be used at a dosage ranging from 1e14 atoms/cm³ to 5e15 atoms/cm³ with an implantation energy ranging from 1 to 5 keV. Phosphorus may be used at a dosage of 1e16 atoms/cm³ with an implantation energy ranging from 5 to 15 keV. Arsenic may be used at a dosage 1e14 atoms/cm³ to 5e15 atoms/cm³ with an implantation energy ranging from 2 to 5 keV. The present inventive concept is not limited thereto.

Doped regions 300, 310 and 320 adjacent to the gate insulation layers 160 and 170 may be formed by the ion implantation process. When exposed to an appropriate etchant, the doped regions 300, 310 and 320 will have a higher etch rate than the material of the first fin type active pattern F1 around the doped regions 300, 310 and 320. Some portions of the doped regions 300, 310 and 320 are positioned under the spacers SP1 to SP4. Here, sizes of the doped regions 300, 310 and 320 (including depths thereof) may vary based on requirements of a transistor to be formed.

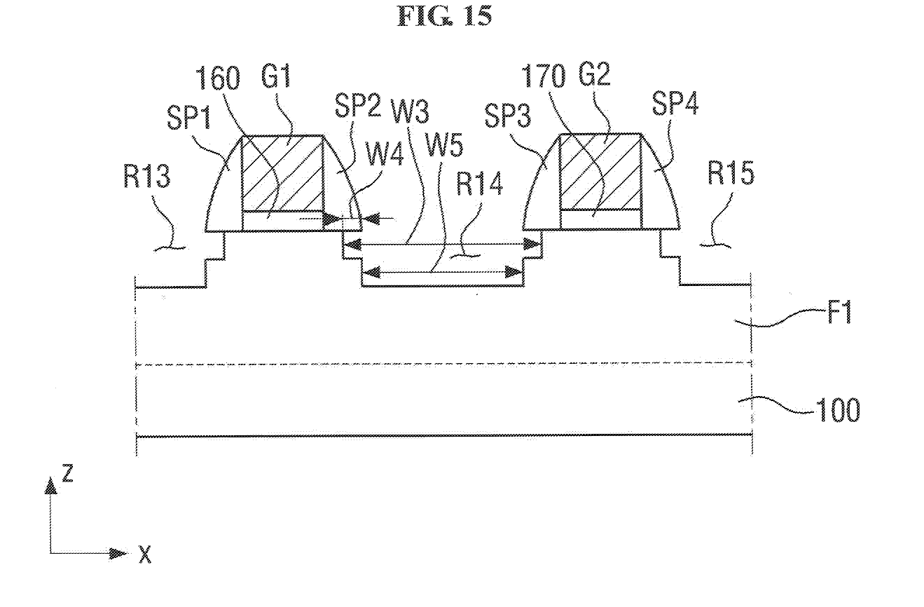

Referring to FIG. 15, the doped regions 300, 310 and 320 of the first fin type active pattern F1 may be formed using a dry etch process. The etched recess regions R13 to R15 are formed to be adjacent to the gate electrodes G1 and G2 and some regions of the recess regions R13 to R15 may be formed under the spacers SP1 to SP4.

For example, top portions of the recess regions R13 to R15 may partially overlap with the spacers SP1 to SP4 and may be formed to have the third width W3, and bottom portions of the recess regions R13 to R15 may be formed to have the fifth width W5. Here, a width of each of the regions partially overlapping with the spacers SP1 to SP4 in the first direction X may be the fourth width W4.

The recess regions R13 to R15 may be etched to a depth in a range between 50 nm and 1500 nm. The depth of the recess regions R13 to R15 may be greater than a thickness of the doped regions 300, 310 and 320. The etching depth of the doped regions 300, 310 and 320 may be appropriately set based on the performance of a transistor to be formed.

The dry etching process may be performed using etchant recipe under which the etch rates of the doped regions 300, 310 and 320 may be increased. Accordingly, the dry etching process allows the material of the first fin type active pattern F1 to be removed faster from the doped regions 300, 310 and 320 than from the other portions of the first fin type active pattern F1.

The etch rates of the doped regions 300, 310 and 320 may be increased by several parameters, including thicknesses of spacers, a processing error of the dry etching process and other processing errors. The spacers SP1 to SP4 may be undercut by the recess regions R13 to R15 resulting from the dry etching process. For example, the dry etching process may use a chlorinated chemistry taking place in a plasma reactor.

Here, the etchant recipe may include a variety of combinations, which will be described hereinafter.

First, the etchant recipe may include NF₃ and Cl₂. Argon or helium gas may be used as a buffer or carrier gas.

The flow rate of the etchant species may vary in a range, for example, between about 50 and about 200 SCCM (standard cubic centimeters per minute) while the flow rate of the carrier gas may vary in a range, for example, between about 150 and about 400 SCCM.

Such etchant species may be activated by high energy plasma where a power may range about 700 W to about 1100 W with a low radio frequency (RF) bias of less than about 100 W. The pressure of the reactor may range from about 1 Pa to about 2 Pa.

The etchant recipe may include a combination of HBr and Cl₂. In addition, the flow rate of etchant species may vary in a range, for example, between about 40 SCCM and about 100 SCCM.

Here, the etchant species of HBr and Cl₂ may be activated by power ranging from about 600 W to about 1000 W with a low RF bias of less than about 100 W. The pressure of the reactor may range from about 0.3 Pa to about 0.8 Pa.

The etchant recipe may include a combination of Ar and Cl₂. In this case, the flow rate of etchant species may vary in a range, for example, between about 40 SCCM and about 80 SCCM.

Here, the etchant species of Cl₂ may be activated by medium energy plasma whose power ranges from about 400 W to about 800 W with a high RF bias of about 100 W to about 200 W. The pressure of the reactor may range from about 1 Pa to about 2 Pa.

The dry etching process may be performed for, for example, about 60 seconds. Such process time may be varied according to an etching depth to be formed and an etchant, for example. The recess regions R13 to R15 may be formed in the first fin type active pattern F1 after the dry etching process is performed.

As described above, the recess regions R13 to R15 may undercut the spacers SP1 to SP4 while etching the doped regions 300, 310 and 320. The formation of the recess regions R13 to R15 is minimally affected by thicknesses of the spacers SP1 to SP4 by using the dopant and etchant recipe capable of increasing the etch rates of the doped regions 300, 310 and 320 during the dry etching process. The dry etching process may be performed in an isotropic etching process.

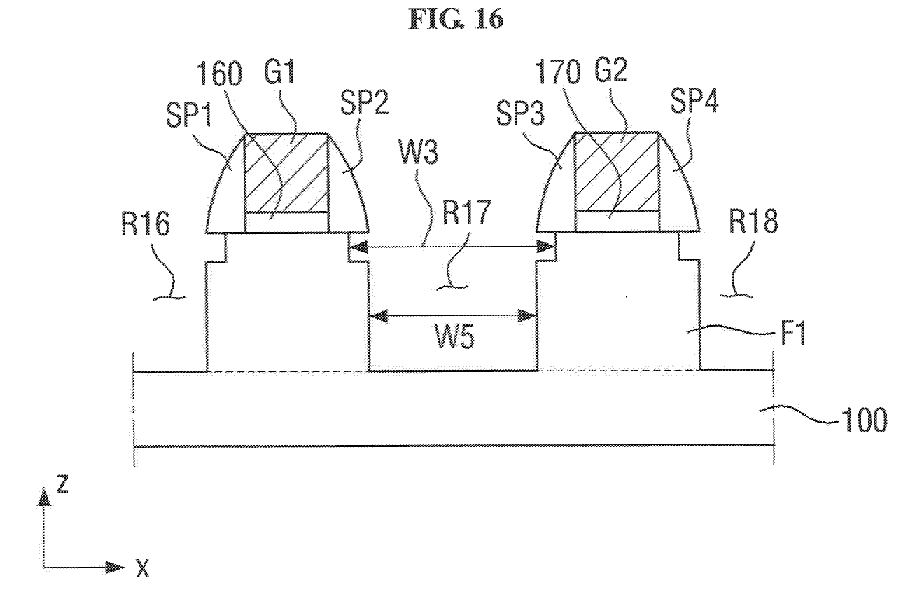

Referring to FIG. 16, a wet etching process is performed on the resulting structure of FIG. 15 to clean the surface of the first fin type active pattern F exposed by the dry etching process as described above.

The wet etching process may clean the surface by removing contaminants, including carbon, chlorine, chlorofluorocarbon, oxide such as silicon dioxide. A subsequent processes may be performed to form the 16th to 18th recess regions R16 to R18. If a single crystal silicon substrate is used, the wet etching process may also be used in removing portion of the first fin type active pattern F1 based on <111> and <001> crystallographic planes for providing a smooth surface for high quality epitaxial deposition. Here, top portions of the recess regions R16 to R18 may partially overlap with the spacers SP1 to SP4 and may be formed to have the third width W3. Bottom portions of the recess regions R16 to R08 may be formed to have the fifth width W5.

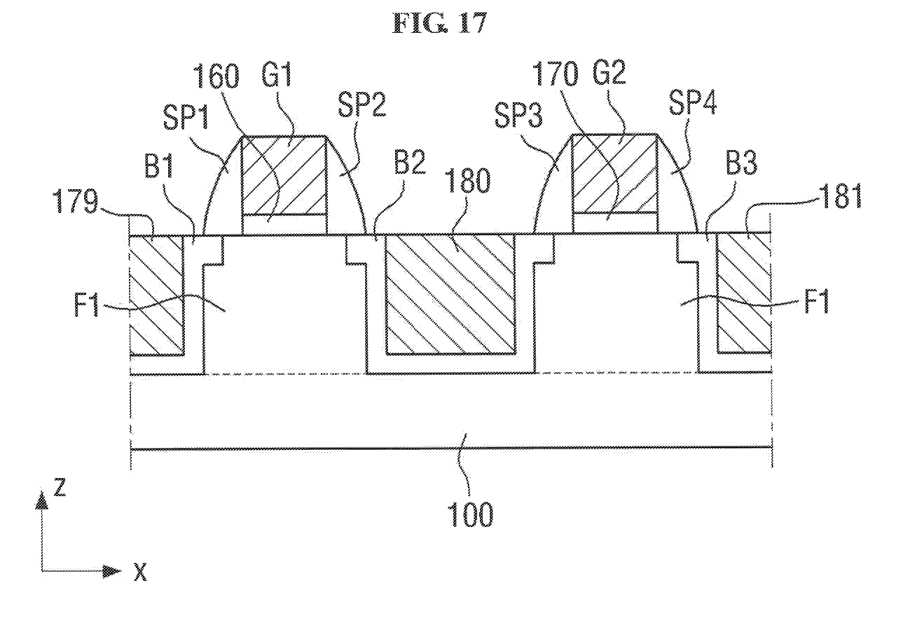

Referring to FIG. 17, the buffer layers B1 to B3 and source/drain regions 179, 180 and 181 are formed by performing the same process steps as shown in FIGS. 12 and 13.

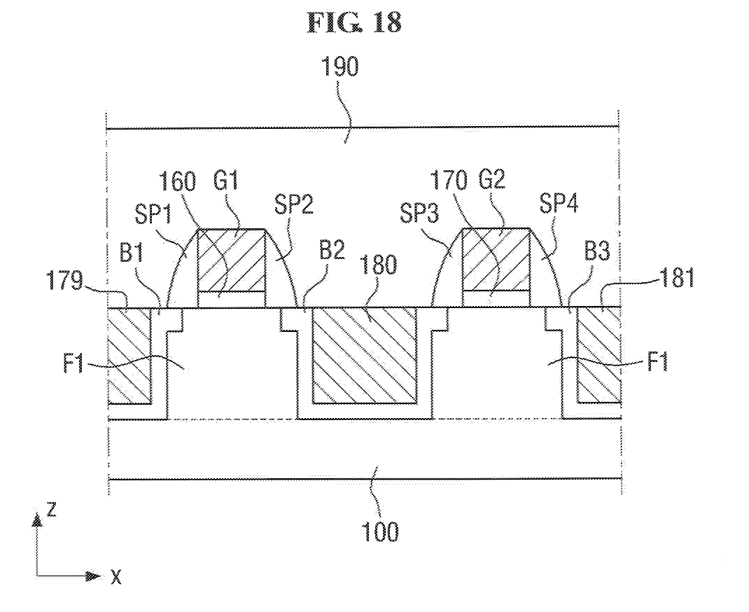

Hereinafter, a method for fabricating the semiconductor device shown in FIG. 5 will be described with reference to FIGS. 18 to 20.

FIGS. 18 to 20 illustrate process steps illustrating a method for fabricating the semiconductor device shown in FIG. 5. The semiconductor device 3 shown in FIG. 5 may be formed using a gate-last process, and the same process steps as shown in FIGS. 7 to 13 may be performed before the process step shown in FIG. 18. Thus, the process steps shown in FIGS. 7 to 13 will not be described, and the following description will be given with regard to the following process steps after the process step shown in FIG. 18.

Referring to FIG. 18, a second interlayer dielectric layer 190 may be formed to cover the gate electrodes G1 and G2 and the spacers SP1 to SP4.

For example, after the second interlayer dielectric layer 190 is formed to cover the gate electrodes G1 and G2 and the spacers SP1 to SP4, a planarization process may be performed to expose the gate electrodes G1 and G2. The planarization process may include, for example, a CMP process, but the present inventive concept is not limited thereto.

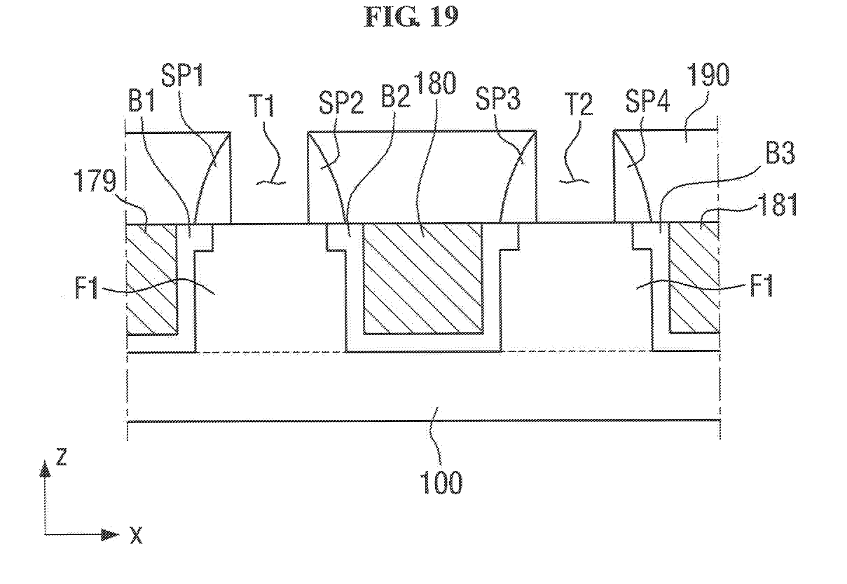

Referring to FIG. 19, trenches T1 and T2 are formed by removing the gate insulation layers 160 and 170 positioned under the exposed gate electrodes G1 and G2 and gate electrodes G1 and G2 after the planarization process.

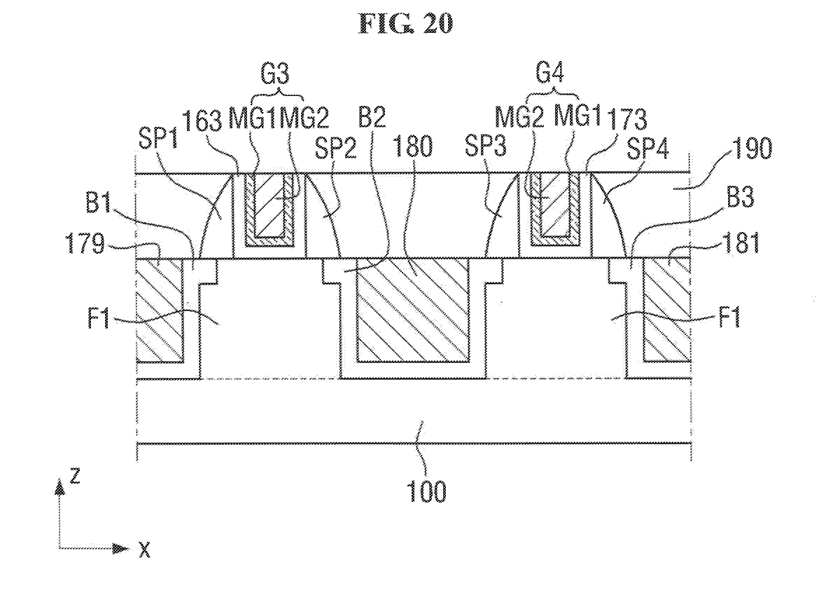

Referring to FIG. 20, the gate insulation layers 163 and 173 and the two or more metal layers MG1 and MG2 are stacked in the trenches T1 and T2. As described above, after the gate insulation layers 163 and 173 and the two or more metal layers MG1 and MG2 are stacked, the remaining second interlayer dielectric layer 190 is removed, thereby fabricating the semiconductor device 2 shown in FIG. 4.

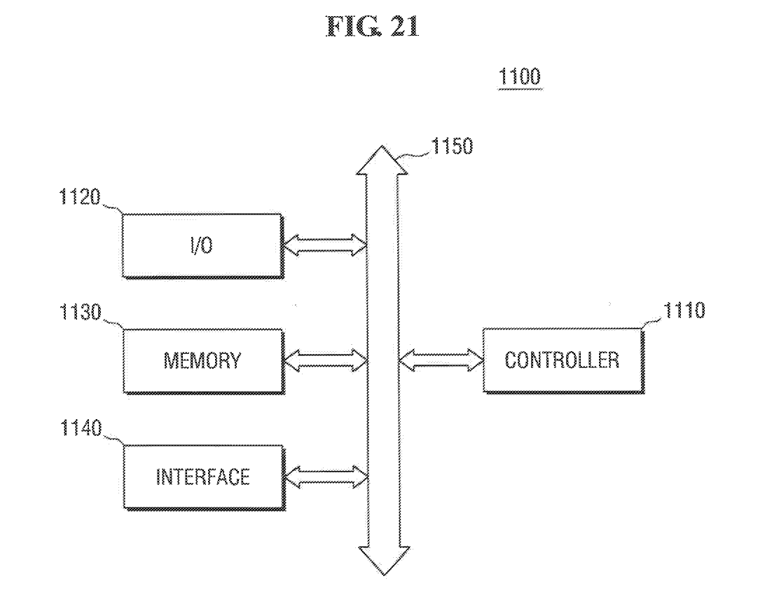

Next, an electronic system including a semiconductor device according to an exemplary embodiment of the present inventive concept will be described with reference to FIG. 21.

FIG. 21 is a block diagram of an electronic system including a semiconductor device according to an exemplary embodiment of the present inventive concept.

Referring to FIG. 21, the electronic system 1100 may include a controller 1110, an input/output device (I/O) 1120, a memory device 1130, an interface 1140 and a bus 1150. The controller 1110, the I/O 1120, the memory device 1130 and/or the interface 1140 may be connected to each other through the bus 1150. The bus 1150 corresponds to a path through which data move.

The controller 1110 may include at least one of a microprocessor, a digital signal processor, a microcontroller, and logic elements capable of functions similar to those of these elements. The I/O 1120 may include a keypad, a keyboard, a display device, and so on. The memory device 1130 may store data and/or codes. The interface 1140 may perform functions of transmitting data to a communication network or receiving data from the communication network. The interface 1140 may be wired or wireless.

For example, the interface 1140 may include an antenna or a wired/wireless transceiver, and so on.

Although not shown, the electronic system 1100 may further include high-speed dynamic random access memory (DRAM) and/or static random access memory (SRAM) as a working memory for the operation of the controller 1110. Here, a semiconductor memory device according to an exemplary embodiment of the present inventive concept may be employed as the above-mentioned memory for the memory controller 1110. The exemplary semiconductor device may be incorporated into the memory device 1130 or may be provided as a component of the controller 1110 or the I/O 1120.

The electronic system 1100 may be applied to a personal digital assistant (PDA), a portable computer, a web tablet, a wireless phone, a mobile phone, a digital music player, a memory card, or any type of electronic device capable of transmitting and/or receiving information in a wireless environment.

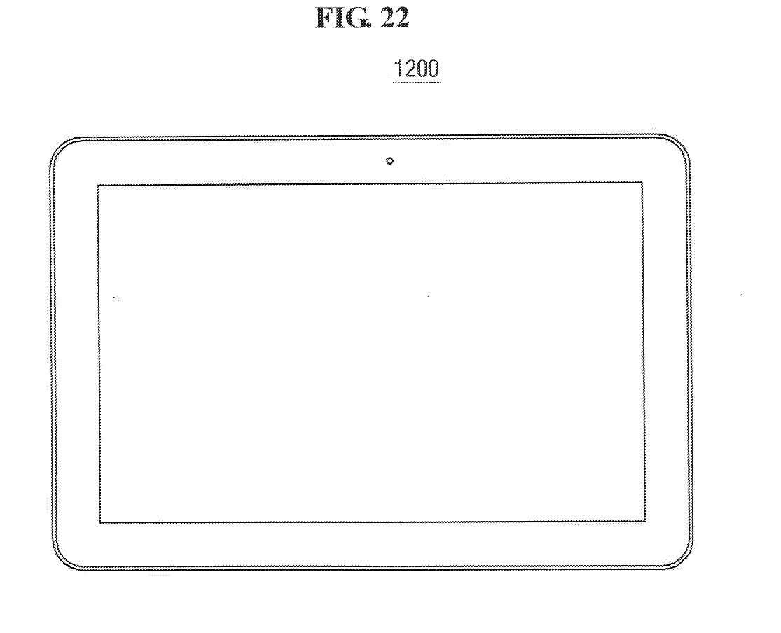

FIGS. 22 to 24 illustrate exemplary semiconductor systems having a semiconductor device according to an exemplary embodiment of the present inventive concept are applied.

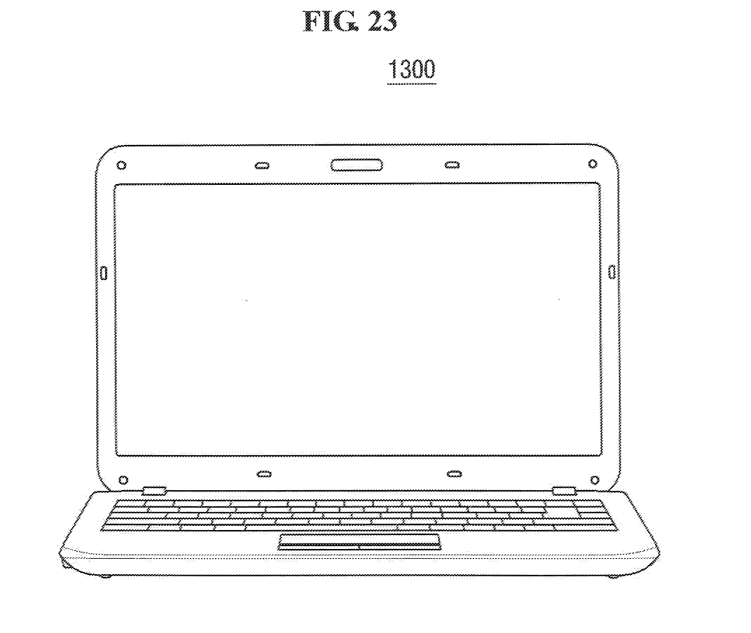

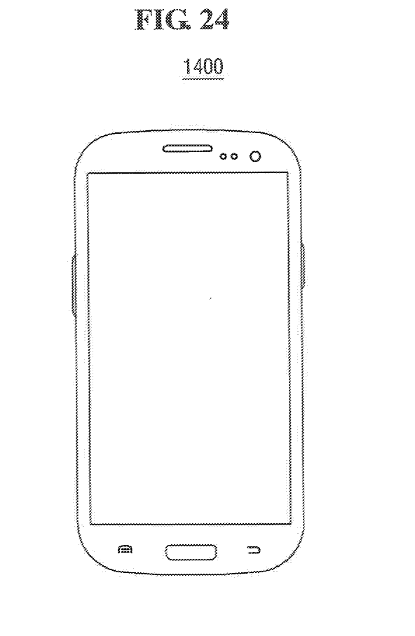

Specifically, FIG. 22 illustrates a tablet PC 1200, FIG. 23 illustrates a notebook computer 1300 and FIG. 24 illustrates a smart phone 1400. A semiconductor device according to an exemplary embodiment of the present inventive concept may be employed to the tablet PC 1200, the notebook computer 1300, the smart phone 1400, and the like.

The inventive concept is not limited thereto. For example, the semiconductor system may be implemented by a computer, an ultra mobile personal computer (UMPC), a work station, a net-book, a personal digital assistant (PDA), a portable computer, a wireless phone, a mobile phone, a smart phone, an e-book, a portable multimedia player (PMP), a portable game console, a navigation device, a black box, a digital camera, a 3-dimensional television, a digital audio recorder, a digital audio player, a digital picture recorder, a digital picture player, digital video recorder, a digital video player, or the like. While the present inventive concept has been shown and described with reference to exemplary embodiments thereof, it will be apparent to those of ordinary skill in the art that various changes in form and detail may be made therein without departing from the spirit and scope of the inventive concept as defined by the following claims.

1. A semiconductor device comprising:
a fin type active pattern protruding from a substrate and extending in a first direction;
a gate electrode disposed on the fin type active pattern, wherein the gate electrode extends in a second direction crossing the first direction;
a recess region disposed in the fin type active pattern disposed at one side of the gate electrode, wherein the recess region includes an upper region having a first width in the first direction and a lower region having a second width smaller than the first width;
a first epitaxial layer formed along a sidewall and a bottom surface of the recess region disposed in the upper and lower regions of the recess region; and
a second epitaxial layer disposed on the first epitaxial layer to fill the recess region,
wherein a third width of the first epitaxial layer disposed in the upper region of the recess region is greater than a fourth width of the first epitaxial layer disposed in the sidewall of the lower region of the recess region, wherein the third width and the fourth width are measured in the first direction.

2. (canceled)

3. The semiconductor device of claim 1, further comprising a spacer disposed on both side surfaces of the gate electrode,
wherein a portion of the first epitaxial layer is disposed underneath the spacer.

4. The semiconductor device of claim 3, wherein a first portion of a top surface of the first epitaxial layer is in contact with a bottom surface of the spacer, and a second portion of the too surface is exposed by the spacer.

5. The semiconductor device of claim 1, wherein the second epitaxial layer is doped with an N- or P-type impurity and the first epitaxial layer is not doped with the N- or P-type impurity.

6. The semiconductor device of claim 1, wherein the first epitaxial layer is doped with an N- or P-type impurity at a first concentration, and the second epitaxial layer is doped with the N- or P-type impurity at a second concentration greater than the first concentration.

7. The semiconductor device of claim 1, wherein the first epitaxial layer is formed of silicon (Si) layer or SiGe layer having a low-concentration germanium (Ge) less than 1e19 atoms/cm³.

8. The semiconductor device of claim 1, wherein the first epitaxial layer is in contact with the second epitaxial layer.

9.-20. (canceled)
